(19) United States
(12) Patent Application Publication
(10) Pub. No.: US 2024/0427250 A1
(43) Pub. Date: Dec. 26, 2024

(54) APPARATUS FOR TREATING SUBSTRATE

(71) Applicant: SEMES CO., LTD., Cheonan-si (KR)

(72) Inventors: Jae Ho LEE, Cheonan-si (KR); Jong Gu LEE, Sangju-si (KR); Dae Sung KIM, Suwon-si (KR); Jae Hyun LIM, Asan-si (KR); Nak Hyun SONG, Cheonan-si (KR)

(73) Assignee: SEMES CO., LTD., Cheonan-si (KR)

(21) Appl. No.: 18/750,169

(22) Filed: Jun. 21, 2024

(30) Foreign Application Priority Data
Jun. 21, 2023 (KR) 10-2023-0079407

(51) Int. Cl. G03F 7/16; G03F 7/00

(52) U.S. Cl. CPC G03F 7/162; G03F 7/707; G03F 7/70733

(57) ABSTRACT

Disclosed is an apparatus for treating a substrate, the apparatus including: a housing having an inner space; a plurality of outer cups arranged in a row in the inner space, each having a processing space; a spin chuck for supporting and rotating a substrate in each of the processing spaces; and a treatment solution nozzle provided in a plurality to correspond to the plurality of outer cups, respectively, and for supplying a treatment solution onto the substrate supported by the spin chuck, in which the outer cup includes a sidewall surrounding the spin chuck, the sidewall includes a first region and a second region located adjacent to each other along a circumferential direction thereof, and the outer cup includes a first protrusion installed in the first region while extending upwardly on a top end of the sidewall.

### CROSS-REFERENCE TO RELATED APPLICATIONS

This application claims priority to and the benefit of Korean Patent Application No. 10-2023-0079407 filed in the Korean Intellectual Property Office on Jun. 21, 2023 the entire contents of which are incorporated herein by reference.

### TECHNICAL FIELD

The present invention relates to an apparatus for treating a substrate, and more particularly, to a substrate treating apparatus for liquid-treating a substrate by supplying a treatment solution to the substrate.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

In the development process, when a treatment solution, such as a developer, is discharged onto the substrate, the film formed on the substrate is removed and discharged together with the treatment solution. Within the development chamber, a plurality of cups may be provided to treat the substrate, and as the number of cups provided within a single chamber increases, the spacing between cups decreases. . . . When the treatment solution, which needs to be discharged through an outlet provided for each cup, is scattered into another cup, particles contained in the treatment solution may contaminate the substrate that is being treated in the other cup, resulting in process failure.

### SUMMARY OF THE INVENTION

The present invention to solve the foregoing problems provides a substrate treating apparatus capable of improving substrate treating efficiency.

The present invention to solve the foregoing problems provides a substrate treating apparatus capable of minimizing contamination of a substrate to minimize process failure.

Further, the present invention to solve the foregoing problems provides a substrate treating apparatus for preventing a treatment solution from being scattered to another outer cup.

The object of the present invention is not limited thereto, and other objects not mentioned will be clearly understood by those of ordinary skill in the art from the following description.

An exemplary embodiment of the present invention provides an apparatus for treating a substrate, the apparatus including: a housing having an inner space; a plurality of outer cups arranged in a row in the inner space, each having a processing space; a spin chuck for supporting and rotating a substrate in each of the processing spaces; and a treatment solution nozzle provided in a plurality to correspond to the plurality of outer cups, respectively, and for supplying a treatment solution onto the substrate supported by the spin chuck, in which the outer cup includes a sidewall surrounding the spin chuck, the sidewall includes a first region and a second region located adjacent to each other along a circumferential direction thereof, and the outer cup includes a first protrusion installed in the first region while extending upwardly on a top end of the sidewall.

According to the exemplary embodiment, the first region may be a region facing another adjacent outer cup.

According to the exemplary embodiment, the sidewall may further include a third region and a fourth region, and the third region may face the first region, and the fourth region may face the second region, and the third region may be provided with a second protrusion extending upwardly from the top end of the sidewall.

According to the exemplary embodiment, the first protrusion and the second protrusion may be provided in a shape of an arc.

According to the exemplary embodiment, the apparatus may further include a nozzle arm for supporting the treatment solution nozzle, in which the nozzle arm may be provided to enter a space surrounded by the first protrusion, the second region, and the second protrusion and be movable to a top of the spin chuck.

According to the exemplary embodiment, the apparatus may further include a transfer robot for transferring the substrate to the spin chuck, in which the transfer robot may be provided to enter a space surrounded by the first protrusion, the fourth region, and the second protrusion to transfer the substrate to the spin chuck.

According to the exemplary embodiment, the first protrusion and the second protrusion each may have the same height extending upwardly from the top end of the sidewall.

According to the exemplary embodiment, the first protrusion and the second protrusion may be provided to be detachably.

According to the exemplary embodiment, a width of the second region in a circumferential direction may be provided to be wider than a width of the first region in a circumferential direction and the third region in a circumferential direction.

According to the exemplary embodiment, the outer cup may further include a top wall, the top wall may be provided to slope upwardly from the top end of the sidewall toward a central axis of the outer cup, and a top end of each of the first protrusion and the second protrusion may be provided to be positioned higher than a top end of the top wall.

Another exemplary embodiment of the present invention provides an apparatus for treating a substrate, the apparatus including: a housing having an inner space; an outer cup provided in the inner space and having a processing space; a spin chuck for supporting and rotating a substrate within the processing space; a treatment solution nozzle for supplying a treatment solution onto the substrate supported by the spin chuck; and a nozzle arm for supporting the treatment solution nozzle, in which the outer cup includes a sidewall surrounding the spin chuck, the outer cup is provided with a protrusion extending upwardly from a top end of the sidewall, and the protrusion is provided only in a portion of the sidewall.

According to the exemplary embodiment, the sidewall may include a first region and a second region located adjacent to each other along a peripheral direction thereof, and the first region may be provided with the protrusion.

According to the exemplary embodiment, the sidewall may further include a third region and a fourth region, and the third region may face the first region, and the fourth region may face the second region, and the protrusion may be further provided in the third region.

According to the exemplary embodiment, the protrusion may be provided in a shape of an arc.

According to the exemplary embodiment, one of spaces between the protrusions may be provided as a space into which the nozzle arm enters.

According to the exemplary embodiment, the apparatus may further include a transfer robot for transferring the substrate to the spin chuck, in which one of the spaces between the protrusions may be provided as a space into which the transfer robot enters.

According to the exemplary embodiment, the outer cup may further include a top wall, the top wall may be provided to slope upwardly from the top end of the sidewall toward a central axis of the outer cup, and a top end of the protrusion may be provided to be positioned higher than a top end of the top wall.

Still another exemplary embodiment of the present invention provides an apparatus for treating a substrate, the apparatus including: a housing having an inner space; and a first outer cup and a second outer cup provided in the inner space, each having a processing space, in which the first outer cup and the second outer cup are arranged in a row in one direction in the inner space, each of the first outer cup and the second outer cup includes: a spin chuck for supporting and rotating a substrate within the processing space; a treatment solution nozzle for supplying a treatment solution onto the substrate supported by the spin chuck; a nozzle arm for supporting the treatment solution nozzle; and a sidewall surrounding the spin chuck, and the first outer cup includes a first region, a second region, a third region, and a fourth region in the sidewall, the first region is provided with a first protrusion extending upwardly from the top end of the sidewall, the first protrusion is provided in a shape of an arc, and the first region is a region facing the second outer cup.

According to the exemplary embodiment, the third region may face the first region, and the fourth region may face the second region, and the third region may be provided with a second protrusion extending upwardly from the top end of the sidewall, and the second protrusion may be provided in a shape of an arc.

According to the exemplary embodiment, the apparatus may further include a transfer robot for transferring the substrate to the spin chuck, in which one of spaces between the first protrusion and the second protrusion may be provided as a space into which the nozzle arm enters, and another one of the spaces between the first protrusion and the second protrusion may be provided as a space into which the transfer robot enters.

According to the exemplary embodiment of the present invention, it is possible to minimize scattering a treatment solution to contaminate a substrate.

According to the exemplary embodiment of the present invention, it is possible to minimize process defect caused by substrate contamination.

According to the exemplary embodiment of the present invention, it is possible to improve substrate treatment efficiency.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a top view schematically illustrating a transfer robot of FIG. 3.

FIG. 6 is a top plan view schematically illustrating one example of a heat treating chamber of FIG. 3 or FIG. 4.

FIG. 7 is a front view of the heat treating chamber of FIG. 6.

FIG. 8 is a top view of one exemplary embodiment of the liquid treating chamber of FIG. 3 or FIG. 4.

FIG. 9 is a cross-sectional view schematically illustrating some configurations of FIG. 8.

FIG. 10 is a diagram illustrating the outer cup of FIG. 9 viewed from above.

FIGS. 11 to 14 are diagrams illustrating a liquid treating chamber according to another exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to devices used for other types of substrate processing, in addition to wafers.

Hereinafter, exemplary embodiments of the present invention will be described with reference to the accompanying drawings.

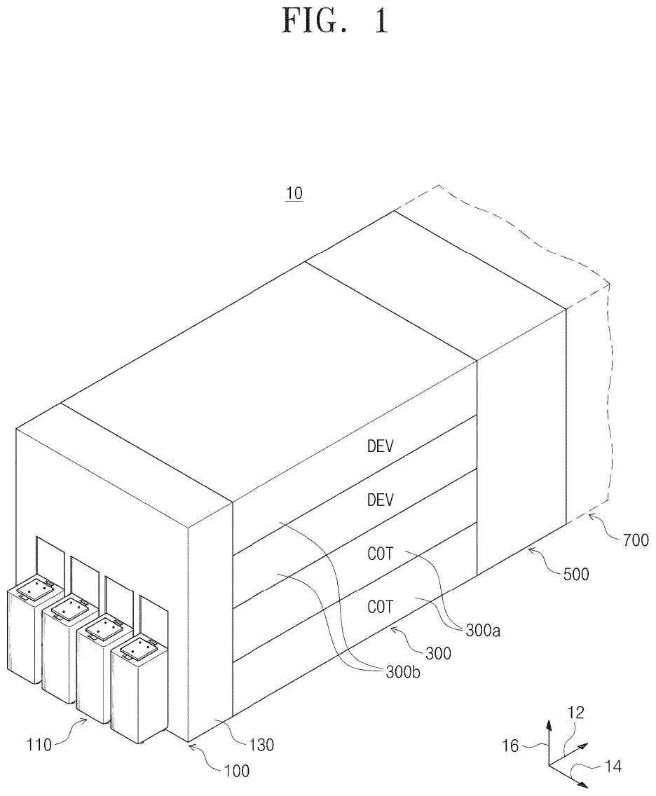

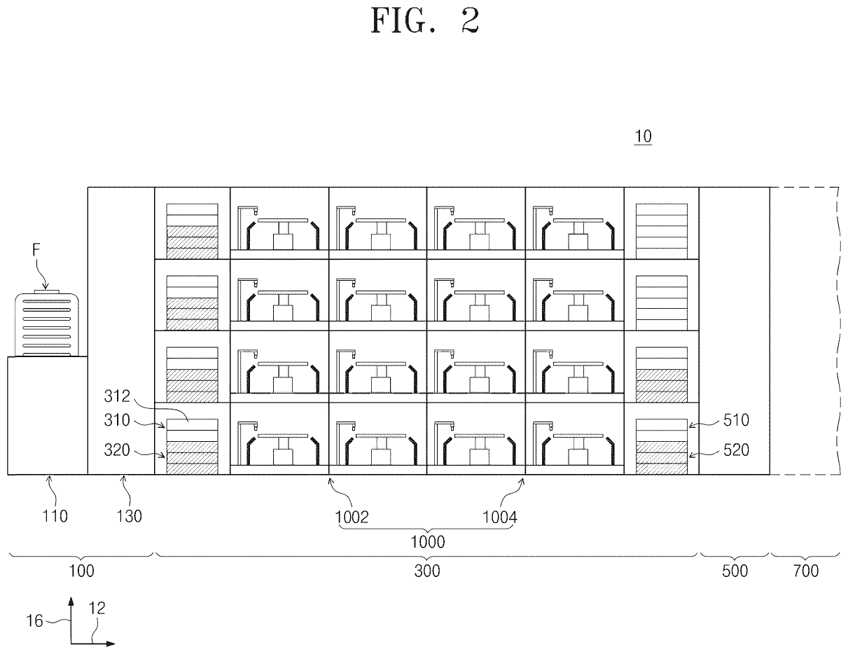

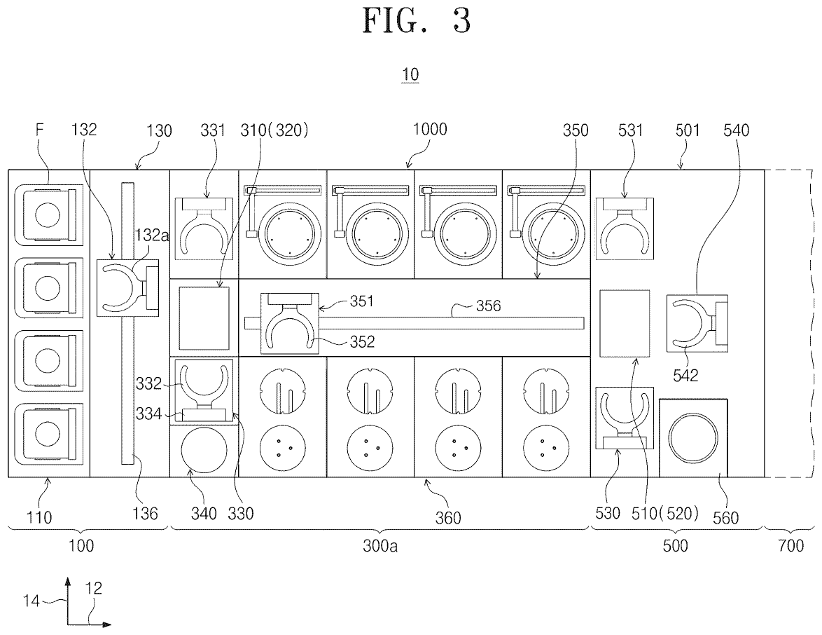

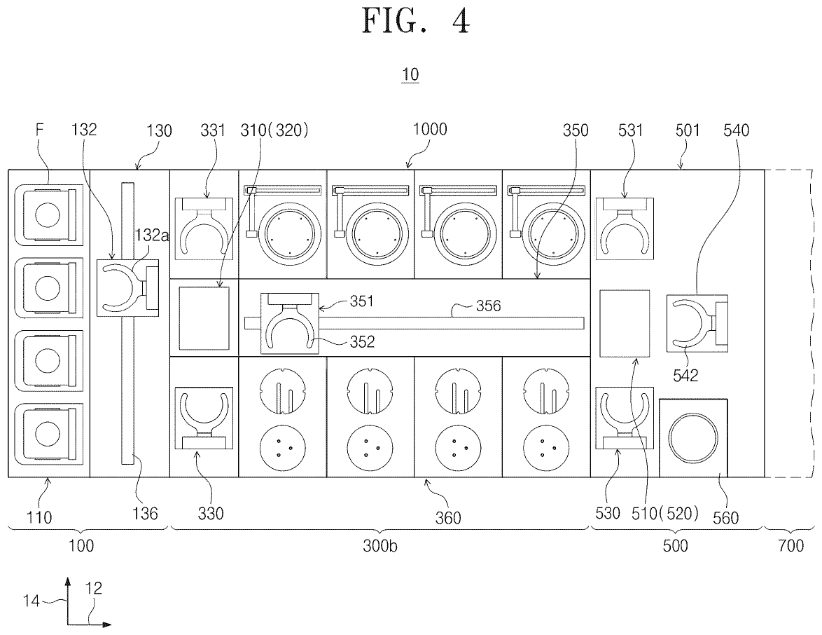

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 4 is a top plan view of a developing block in the substrate treating apparatus of FIG. 1.

Referring to FIGS. 1 to 4, a substrate processing apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the processing module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the processing module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the processing module 300 relative to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The treating module 300 performs an application process and a development process on the substrate W. The processing module 300 includes a coating block 300a and a developing block 300b.

The applying block 300a performs an application process on the substrate W before the exposure process. The developing block 300b performs a development process on the substrate W after the exposure process. A plurality of applying blocks 300a is provided. The plurality of applying blocks 300a may be provided while being stacked on top of each other. A plurality of developing blocks 300b is provided. The plurality of developing blocks 300b may be provided to be stacked with each other. In one example, two applying blocks 300a are provided and two developing blocks 300b are provided. The plurality of applying blocks 300a may be positioned below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structures as each other. A developer supplied to the substrate W in the plurality of developer blocks 300b may be the same type of liquid. Optionally, the developer supplied to the substrate W may be different types of developer depending on the developing blocks 300b.

Referring to FIG. 3, the applying block 300a includes a buffer unit 310, a cooling unit 320, a hydrophobization chamber 340, a transfer chamber 350, a heat treating chamber 360, and a liquid treating chamber 1000.

The buffer unit 310, the cooling unit 320, and the hydrophobization chamber 340 are disposed adjacent to the index module 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the processing module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided relative to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be positioned adjacent to the interface module 500.

A plurality of heat treating chambers 360 is provided. Some of the heat treating chambers 360 is disposed along the first direction 12. Additionally, some of the heat treating chambers 360 may be stacked along the third direction 16. The heat treating chambers 360 may all be located on one side of the transfer chamber 350.

The liquid treating chamber 1000 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 1000 is provided. The liquid treating chambers 1000 may be located on the side opposite the heat treating chamber 360. For example, all of the liquid treating chambers 1000 may be located on the other side of the transfer chamber 350. The liquid treating chambers 1000 are arranged side-by-side along the first direction 12. Optionally, some of the liquid treating chambers 1000 may be stacked along the third direction 16.

In one example, the liquid treating chambers 1000 include a front end liquid treating chamber 1002 and a rear end liquid treating chamber 1004. The front end liquid treating chamber 1002 is disposed relatively close to the index module 100, and the rear end liquid treating chamber 1004 is disposed more close to the interface module 500.

The front end liquid treating chamber 1002 applies a first liquid onto the substrate W, and the rear end liquid treating chamber 1004 applies a second liquid onto the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300b includes a buffer unit 310, a cooling unit 320, a transfer chamber 350, a heat treating chamber 360, and a liquid treating chamber 1000. The arrangement of the buffer unit 310, the cooling unit 320, the transfer chamber 350, the heat treating chamber 360, and the liquid treating chamber 1000 in the developing block 300b may be the same as the arrangement of the buffer unit 310, the cooling unit 320, the transfer chamber 350, the heat treating chamber 360, and the liquid treating chamber 1000 in the applying block 300a. When viewed from above, the buffer unit 310, the cooling unit 320, the transfer chamber 350, the heat treating chamber 360, and the liquid treating chamber 1000 in the developing block 300b and the buffer unit 310, the cooling unit 320, the transfer chamber 350, the heat treating chamber 360, and the liquid treating chamber 1000 in the applying block 300 may be disposed in overlapping positions.

The heat treating chamber 360 performs a heating process on the substrate W. The heating process includes a post-exposure baking process performed on the substrate W after the exposure process is completed, and a hard baking process performed on the substrate W after the development process is completed.

The liquid treating chamber performs the development process by supplying a developer onto the substrate W and developing the substrate W.

In FIG. 3 or FIG. 4, the transfer chamber 350 is provided with a transfer robot 351. The transfer robot 351 transfers the substrate W between the buffer unit 310, the cooling unit 320, the heat treating chamber 360, the liquid treating chamber 1000, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

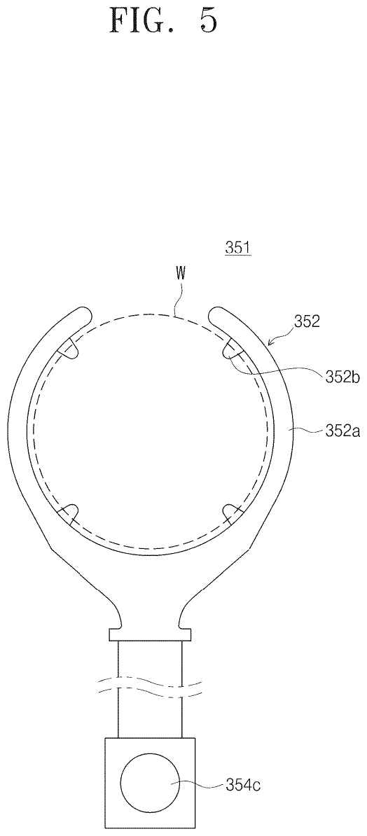

FIG. 5 is a diagram illustrating one example of the hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

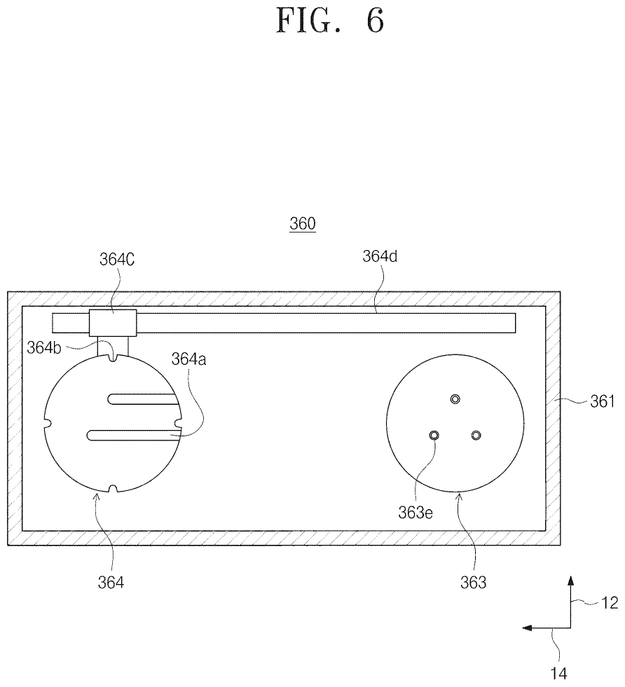

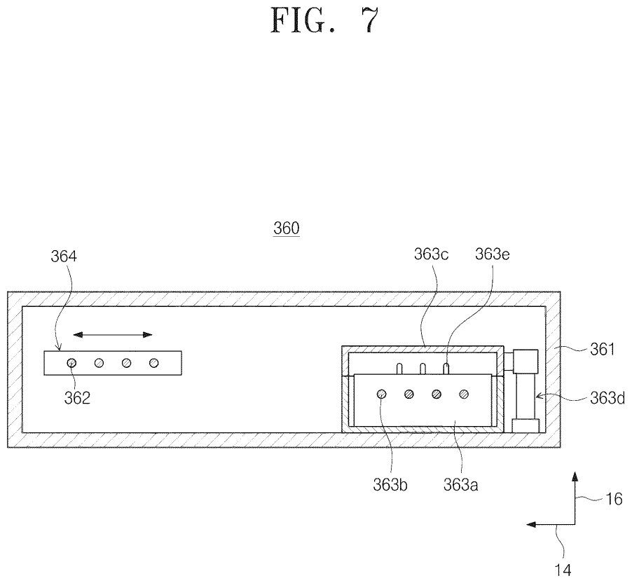

FIG. 6 is a top plan view schematically illustrating an example of the heat treating chamber of FIG. 3 or FIG. 4, and FIG. 7 is a front view of the heat treating chamber of FIG. 6.

Referring to FIGS. 6 and 7, the heat treating chamber 360 includes a housing 361, a heating unit 363, and a transfer plate 364.

The housing 361 is provided in the shape of a generally rectangular parallelepiped. In the sidewall of the housing 361, an entrance opening (not illustrated) is formed through which the substrate W enters and exits. The entrance opening may remain open. Optionally, a door (not illustrated) may be provided to open and close the entrance opening. The heating unit 363 and the transfer plate 364 are provided within the housing 361.

The heating unit 323 includes a heating plate 363a, a cover 363c, and a heater 323b. The heating plate 363a has a generally circular shape when viewed from the top. The heating plate 363a has a larger diameter than the substrate W. The heater 363b is installed on the heating plate 363a. The heater 363b may be provided as a heating wire or heating pattern that is heated by the supply of electrical power. The heating plate 363a is provided with a lift pin 363e. The lift pin 363e is provided to be movable in an upward and downward direction along the third direction 16. The lift pin 363e receives the substrate W from the transfer robot 351 and places the received substrate W on the heating plate 363a, or lifts the substrate W from the heating plate 363a and hands the substrate over to the transfer robot 351. According to the example, three lift pins 363e may be provided. The cover 363c has a space with an open lower portion therein. The cover 363c is located above the heating plate 363a and is moved in a vertical direction by a driver 363d. The space formed by the cover 363c and the heating plate 363a according to the movement of the cover 363c is provided as a heating space for heating the substrate W.

The transfer plate 364 is provided in a substantially disk shape, and has a diameter corresponding to that of the substrate W. A notch 364b is formed at an edge of the transfer plate 364. The notch 364b may have a shape that corresponds to the protrusion 352b formed on the hands 352 of the transfer robot 351 described above. Further, the notches 364b are provided in a number corresponding to the protrusions 352b formed on the hand 352, and are formed at locations corresponding to the protrusions 352b. In a position in which the hand and the transfer plate 364 are arranged in the vertical direction, the substrate W is transferred between the hand 354 and the transfer plate 364 when the vertical position of the hand and the transfer plate 364 is changed. The transfer plate 364 is mounted on a guide rail 364d, and may be movable along the guide rail 364d by the driver 364c.

A plurality of slit-shaped guide grooves 364a is provided in the transfer plate 364. The guide grooves 364a extend from a distal end of the transfer plate 364 to an interior of the transfer plate 364. The longitudinal direction of the guide groove 364a is provided along the second direction 14, and the guide grooves 364a are spaced apart from each other along the first direction 12. The guide groove 364a prevents the transfer plate 364 and the lift pins 363e from interfering with each other when the substrate W is transferred between the transfer plate 364 and the heating unit 363.

The transfer plate 364 is provided with a thermally conductive material. In one example, the transfer plate 364 may be provided from a metal material.

A cooling channel 364 is formed in the transfer plate 362. The cooling channel 362 is supplied with coolant. The substrate W, which has been heated in the heating unit 363, may be cooled while being transferred by the transfer plate 364. Also, the substrate W may be cooled on the transfer plate 364 while the transfer plate 364 is stopped for the substrate W to be taken over by the transfer robot 351.

Optionally, a cooling unit may be further provided within the housing 361. In this case, the cooling unit may be arranged in parallel with the heating unit 363. The cooling unit may be provided as a cooling plate having a passage formed therein through which coolant flows. The substrate that has been heated in the heating unit may be returned to the cooling unit for cooling.

The interface module 500 connects the processing module 300 with an external exposure device 700. The interface module 500 has an interface frame 501, a buffer unit 510, a cooling unit 520, a transfer mechanism 530, an interface robot 540, and an additional process chamber 560.

The top of the interface frame 501 may be provided with a fan filter unit forming a downward airflow therein. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the processing module 300. The buffer unit 510 and the cooling unit 520 are disposed adjacent to the end of the transfer chamber 350. The substrate W that is transferred between the processing module 300, the cooling unit 520, the additional process chamber 560, and the exposure device 700 may temporarily stay in the buffer unit 510. The cooling unit 520 may only be provided at a height corresponding to the applying block 300a between the applying block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the processing module 300. Another transfer mechanism 531 may be further provided in a region opposite the region where the transfer mechanism 530 is provided relative to the buffer unit 510.

The interface robot 540 is disposed between the buffer unit 510 and the exposure device 700. The interface robot 540 is provided to transfer the substrate W between the buffer unit 510, the cooling unit 520, the additional process chamber 560, and the exposure unit 700. The interface robot 540 has a hand 542 on which the substrate W is placed, and the hand 542 may be provided to be movable forwardly and backwardly, rotatable about an axis parallel to the third direction 16, and movable along the third direction 16.

The additional process chamber 560 may perform a predetermined additional process before the substrate W processed in the applying block 300a is loaded to the exposure device 700. Optionally, the additional process chamber 560 may perform a predetermined additional process before the substrate W processed in the exposure device 700 is loaded to the developing block 300b. In one example, the additional process may be an edge exposure process that exposes an edge region of the substrate W, or a top surface cleaning process that cleans the top surface of the substrate W, or a bottom surface cleaning process that cleans the bottom surface of the substrate W, or an inspection process that performs a predetermined inspection on the substrate W. A plurality of additional process chambers 560 may be provided, which may be stacked on top of each other.

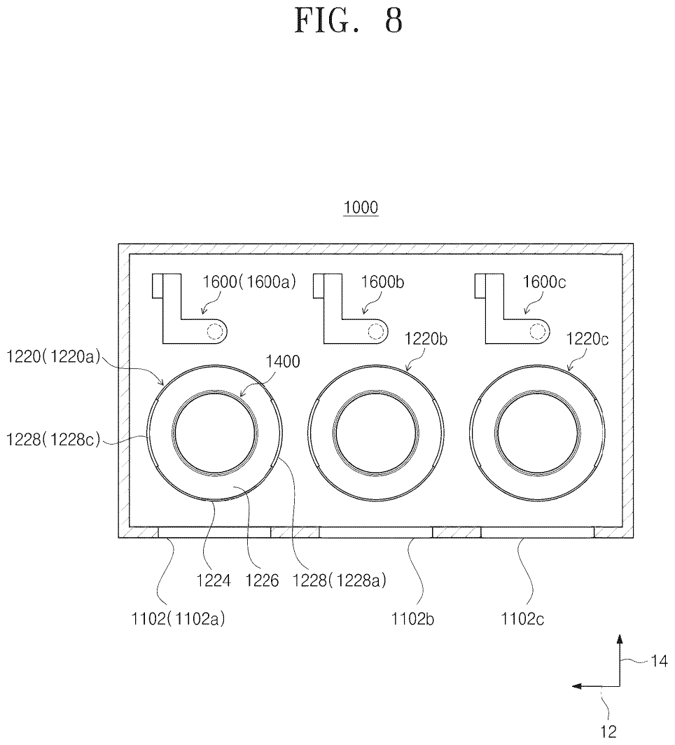

Hereinafter, one exemplary embodiment of the liquid treating chamber of the present invention will be described with reference to FIGS. 8 to 10.

FIG. 8 is a top view of one exemplary embodiment of the liquid treating chamber of FIG. 3 or FIG. 4.

Referring to FIG. 8, the liquid treating chamber 1000 has a housing 1100, an outer cup 1220, a spin chuck 1400, and a liquid supply unit 1600.

The housing 1100 is provided in a rectangular cylindrical shape having an inner space. An opening 1102 is formed in one side of the housing 1100. The opening 1102 functions as a passageway through which the substrate W enters and exits. A door (not illustrated) is installed in the opening 1102, which opens and closes the opening.

The inner space of the housing 1100 is provided with an outer cup 1220. The outer cup 1220 may be provided in a plurality. In this case, the plurality of outer cups 1220 is arranged in a row in the inner space of the housing 1100. FIG. 8 illustrates three outer cups 1220, that is, a first outer cup 1220a, a second outer cup 1220b, and a third outer cup 1220c. The direction in which the outer cups 1220a, 1220b, and 1220c are disposed is the direction parallel to the first direction 12. The opening 1102 is provided in the outer wall of the housing 1100 corresponding to the outer cup 1220. A plurality of openings 1102 may be provided to correspond to a plurality of outer cups 1220. The direction in which the openings 1102a, 1102b, and 1102c are disposed is the direction parallel to the first direction 12.

The liquid supply unit 1600 supplies the treatment solution onto the substrate W. When the liquid treating chamber 1000 is provided in the applying block 300a, the treatment solution may be a liquid for forming a photoresist film, an anti-reflective film, or a protective film. When the liquid treating chamber 1000 is provided in the developing block 300b, the treatment solution may be a developer liquid.

The liquid supply unit 1600 may be provided in a plurality to correspond to a plurality of outer cups 1220. The liquid supply units 1600a, 1600b, and 1600c are disposed side by side along the first direction 12. The liquid supply unit 1600 is disposed on the opposite side of the opening 1102 relative to the outer cup 1220. The liquid supply unit 1600 includes a treatment solution nozzle 1620, which will be described later.

The opening 1102, the outer cup 1220, and the liquid supply unit 1600 are disposed in sequence along the second direction 14.

Since each outer cup 1220 in FIG. 8, and the configuration of the spin chuck 1400 and liquid supply unit 1600 corresponding to the outer cup 1220, is identical, the outer cup 1220 will be described herein with reference to the first outer cup 1220a.

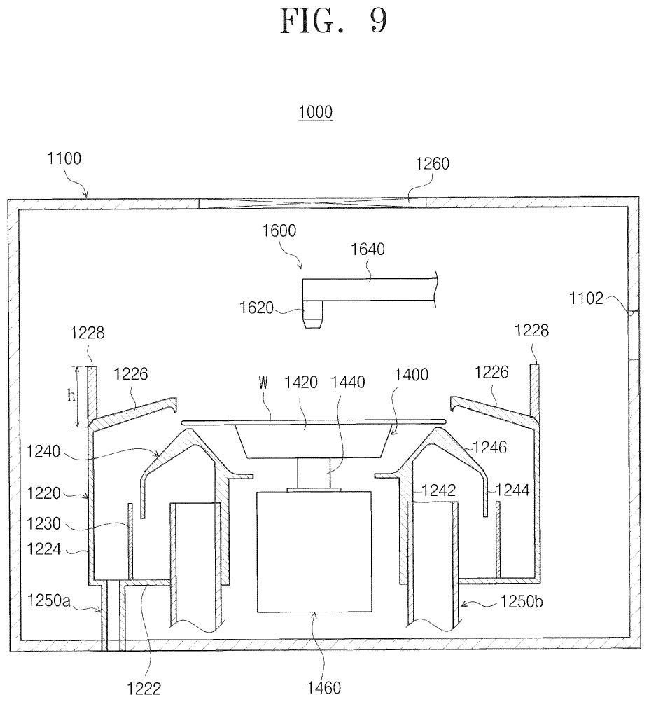

FIG. 9 is a cross-sectional view schematically illustrating some configurations of FIG. 8.

The outer cup 1220 has a processing space with an open top. A spin chuck 1400 supports the substrate W within the processing space of the outer cup 1220. The spin chuck 1400 has a support plate 1420, a rotation shaft 1440, and a driver 1460. The support plate 1420 is provided with a circular top surface. The support plate 1420 has a diameter smaller than the substrate W. The support plate 1420 is provided to support the substrate W under vacuum pressure. A rotation shaft 1440 is coupled to the center of the bottom surface of the support plate 1420, and the rotation shaft 1440 is provided with the driver 1460 that provides rotational force to the rotation shaft 1440. The driver 1460 may be a motor. Additionally, an elevation driver (not illustrated) may be provided to adjust the relative height of the support plate 1420 and the outer cup 1220.

The liquid supply unit 1600 has a treatment solution nozzle 1620, a nozzle arm 1640, and a liquid supply source (not illustrated). The treatment solution nozzle 1620 dispenses a treatment solution onto the substrate W. The treatment solution nozzle 1620 is supported by the nozzle arm 1640. The nozzle arm 1640 moves the treatment solution nozzle 1620 between the process position and the standby position. In the process position, the treatment solution nozzle 1620 supplies a treatment solution to the substrate W placed on the support plate 1420, and after completing the supply of treatment solution, the treatment solution nozzle 1620 waits in the standby position.

The standby position for the treatment solution nozzle 1620 is provided on the opposite side of the opening 1102, centered on the outer cup 1220. The treatment solution nozzle 1620 may move in a straight line in a direction parallel to the second direction 14.

On the top wall of the housing 1100 is disposed a fan filter unit 1260 that provides a downward airflow into the inner space. The fan filter unit 1260 has a fan to introduce air from the outside into the inner space and a filter to filter the outside air.

The outer cup 1220 has a bottom wall 1222, a sidewall 1224, a top wall 1226, and protrusions 1228. The interior of the outer cup 1220 is provided with an inner space as described above. The inner space includes a processing space at the top and an exhaust space at the bottom.

The bottom wall 1222 is provided in a circular shape. An opening is formed in the center of the bottom wall. The sidewall 1224 extends upwardly from an outer end of the bottom wall 1222. The sidewall 1224 is provided in a ring shape and is provided perpendicular to the bottom wall 1222. In one example, the sidewall 1224 extends to the same height as the top surface of the support plate 1420. Optionally, the sidewall may extend to a height slightly lower than the top surface of the support plate 1420.

The top wall 1226 has a circular ring shape. The top wall 1226 has an opening in the center of the top wall 1226. The top wall 1226 is provided to slope upwardly from the top of the sidewall 1224 toward the center axis of the outer cup 1220.

The protrusion 1228 is provided to extend upwardly from the top of the sidewall 1224.

The protrusion 1228 is provided in an arc shape.

The top end of the protrusion 1228 extending upwardly from the top end of the sidewall 1224 is provided to be positioned higher than the top end of the top wall.

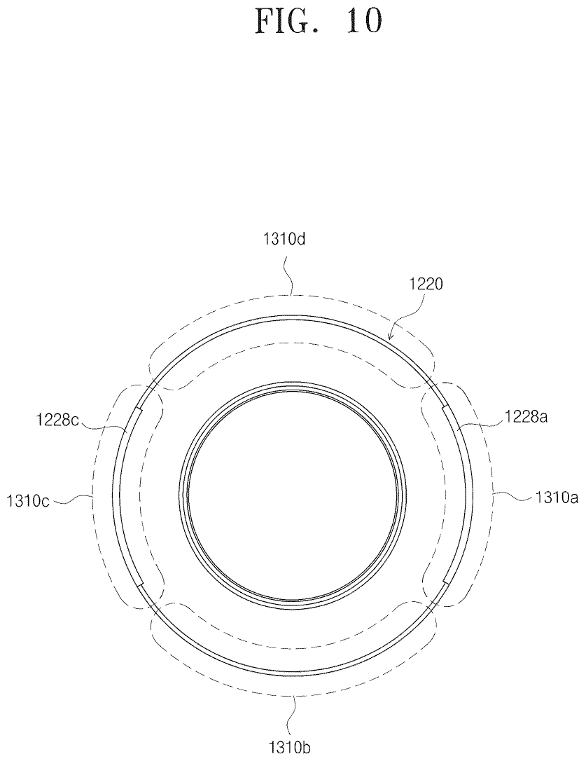

The protrusion 1228 is to be described in more detail with further reference to FIG. 10.

FIG. 10 is a diagram illustrating the outer cup of FIG. 9 viewed from above. The sidewall 1224 of the outer cup 1220 is provided with a first region 1310a, a second region 1310b, a third region 1310c, and a fourth region 1310d.

Each region is located adjacent to the other in the circumferential direction of the sidewall 1224. The first region 1310a may be a region facing another adjacent outer cup.

The third region 1310c is a region facing the first region 1310a, and the fourth region 1310d is a region facing the second region 1310b. The first region 1310a and the third region 1310c are disposed in a direction parallel to the first direction 12. The second region 1310b and the fourth region 1310d are disposed in a direction parallel to the second direction 14.

The protrusions 1228 are installed in some regions of the sidewall 1224. In the present exemplary embodiment, a first protrusion 1228a is installed in the first region 1310a and a second protrusion 1228c is installed in the third region 1310c.

Since the sidewall 1224 is provided in a ring shape, and the protrusions 1228a and 1228c are installed to extend in a height direction from the sidewall 1224, the protrusions 1228a and 1228c are provided in an arc shape.

A substrate transfer space is provided by the fourth region 1310d, the first protrusion 1228a, and the second protrusion 1228c. The substrate transfer space is a space on the top of the sidewall 1224 surrounded by the first protrusion 1228a, the fourth region 1310d, and the second protrusion 1228c, and is provided in the second region 1310b.

A nozzle entry space is provided by the first protrusion 1228a, the second protrusion 1228c, and the second region 1310b. The nozzle entry space is a space on the top of the sidewall 1224 surrounded by the first protrusion 1228a, the second region 1310b, and the second protrusion 1228c, and is provided in the fourth region 1310d.

The width of each region is proportional to the length of the arc of the sidewall 1324 of each region or the width in the circumferential direction of the sidewall 1324.

The first region 1310a and the third region 1310c have the same width in the circumferential direction of the sidewall 1224. In addition, the second region 1310b and the fourth region 1310d have the same width in the circumferential direction of the sidewall 1224.

The widths of the second region 1310b and the fourth region 1310d are provided to be wider than the widths of the first region 1310a and the third region 1310c. That is, the central angle that the second region 1310b and the fourth region 1310d form with the circumferential center of the sidewall 1224 is greater than 90°. The central angle that the first region 1310a and the third region 1310c form with the circumferential center of the sidewall 1224 is less than 90°.

The second region 1320b is provided with a width that is wider than the diameter of the substrate W, as the hand 352 of the transfer robot 351 and the substrate W need to be able to enter and exit the substrate transfer space provided in the second region 1310b.

Because the fourth region 1320d needs to allow the treatment solution nozzle 1620 or nozzle arm 1640 to enter and exit the nozzle entry space provided in the fourth region 1310d, the width of the fourth region 1320d is provided to be wide enough to allow the treatment solution nozzle 1620 or nozzle arm 1640 to enter and exit.

The first protrusion 1228a and the second protrusion 1228c are provided with the same height extending upwardly from the top of the sidewall 1224.

The guide cup 1240 is positioned on the inner side of the outer cup 1220. The guide cup 1240 has an inner wall 1242, an outer wall 1244, and a top wall 1246. The inner wall 1242 has a through-hole that is perforated in an upward and downward direction. The inner wall 1242 is disposed to enclose the driver 1460. The inner wall 1242 minimizes exposure of the driver 1460 to airflow in the processing space. The rotation shaft 1440 of the spin chuck 1400 and/or the driver 1460 extends up and down through the through-hole. The outer wall 1244 is spaced apart from the inner wall 1242 and is disposed to surround around the inner wall 1242. The outer wall 1244 is spaced apart from the sidewall 1224 of the outer cup 1220. The inner wall 1242 is spaced upwardly from the bottom wall 1222 of the outer cup 1220. The top wall 1246 connects the top end of the outer wall 1244 to the top end of the inner wall 1242. The top wall 1246 has a ring shape and is disposed to surround the support plate 1420. In one example, the top wall 1246 has an upwardly convex shape.

The space below the support plate 1420 in the processing space may be provided as an exhaust space. In one example, the exhaust space may be defined by the guide cup 1240. The space enclosed by the outer wall 1244, the top wall 1246, and the inner wall 1242 of the guide cup 1240 and/or the space beneath the space may be provided as an exhaust space.

The outer cup 1220 may be provided with a gas-liquid separation plate 1230. The gas-liquid separation plate 1230 may be provided to extend upwardly from the bottom wall 1222 of the outer cup 1220. The gas-liquid separation plate 1230 may be provided in a ring shape. The gas-liquid separation plate 1230 may be positioned between the sidewall 1224 of the outer cup 1220 and the outer wall 1244 of the guide cup 1240 when viewed from above. The top end of the gas-liquid separator plate 1230 may be positioned lower than the bottom end of the outer wall 1244 of the guide cup 1240.

The bottom wall 1222 of the outer cup 1220 is connected to an outlet pipe 1250a and an exhaust pipe 1250b for discharging the treatment solution. The discharge pipe 1250a may be connected to the outer cup 1220 from the outer side of the gas-liquid separation plate 1230. The exhaust pipe 1250b may be connected to outer cup 1220 in the inner side of gas-liquid separation plate 1230.

Although not illustrated, a lifting driver may be provided to adjust the relative height of the support plate 1420 and the outer cup 1220. In one example, the lifting driver may raise and lower the outer cup 1220 in the vertical direction. For example, the support plate 1420 is positioned at a height higher than the top end of the outer cup 1220 to prevent the transfer member transferring the substrate W from interfering with the outer cup 1220 when the substrate W is loaded onto the support plate 1420 or the substrate W is unloaded from the support plate 1420. Additionally, the support plate 1420 is positioned at a lower height than the top end of the outer cup 1220 so that the substrate W is located within the processing space during processing.

As described above, the transfer robot 351 has a hand 352 on which the substrate W is placed. The hand 352 moves along the second direction 14 to transfer the substrate W on the spin chuck 1400.

In this case, the transfer robot 351 enters the substrate transfer space described above and transfers the substrate W to the spin chuck 1400. That is, the hand 352 of the transfer robot 351 passes through the substrate transfer space and transfers the substrate W to the spin chuck 1400.

After the substrate W is transferred, the nozzle arm 1640 enters the top of the spin chuck 1400 through the nozzle entry space described above. That is, the nozzle arm 1640 passes through the nozzle entry space as the treatment solution nozzle 1620 moves in a straight line from the outer side of the outer cup 1220 to the inner side of the outer cup 1220.

After reaching the top of the spin chuck 1400, the treatment solution nozzle 1620 discharges the treatment solution onto the substrate W placed on the spin chuck 1400.

When the liquid treating chamber 1000 is provided in the developing block 300b, the treatment solution may be a developer. This removes a portion of the photoresist applied to the substrate W. The removed photoresist particles, along with the treatment solution, are discharged through the outer cup 1220.

At this time, due to centrifugal force of the spin chuck 1400 rotating, the treatment solution, such as the developer, may be scattered outside the substrate or into the processing space. While most of the scattered treatment solution is received inside the outer cup 1220, some treatment solution may be scattered to the outside of the outer cup 1220. In this case, when the treatment solution is scattered onto another substrate W being treated in another adjacent outer cup 1220, the treatment solution or particles contained in the treatment solution may contaminate the other substrate W and cause process failure.

By providing the protrusions 1228 on the outer cup 1220, the treatment solution and particles contained in the treatment solution may be prevented from scattering outside of the outer cup 1220. The treatment solution is directed into the interior of the outer cup 1220 by striking the protrusions 1228, thereby minimizing the scattering of the treatment solution and particles contained in the treatment solution into other adjacent outer cups or, in particular, into the processing space of other outer cups, thereby minimizing process defaults.

The protrusion 1228 needs to protrude at a suitable height to minimize spattering of the treatment solution. The height of the protrusion protruding upwardly from the top end of the sidewall 1224 needs to be such that the outer cup 1220 is disposable in the inner space of the housing 1100 without interruption. The protrusion is also provided at a height such that the protrusion does not impede airflow circulation within the housing 1100. The protrusion is also provided at a height that is sufficient to prevent scattering of the treatment solution into the adjacent outer cup. For example, the protrusion 1228 may have a protrusion height of about 30 mm or more.

The protrusion 1228 may be removably provided. In this case, the protrusions 1228 may be removed to perform cleaning or may be replaced when the liquid treatment of the substrate W is terminated or during maintenance of the liquid treating chamber 1000.

In the example described above, the developing chamber 1000, which is the liquid treating chamber provided in the developing block 300b, is described as having the structure with the protrusions 1228. However, it is also possible for the applying chamber provided in the applying block 300a to have a structure with the protrusions 1228.

The present invention is described based on the apparatus for performing the application process or the developing process as an example. However, in contrast to this, the structure having the protrusion 1228, such as the liquid treating chamber 1000 described above, may also be provided in the apparatus for performing cleaning of the substrate W by supplying a cleaning liquid.

In the example described above, three outer cups 1220 are provided in the liquid treating chamber 1000. However, alternatively, one or more outer cups 1220 may be provided in the liquid treating chamber 1000.

In the examples described above, the protrusions 1228, namely the first protrusion 1228a and the second protrusion 1228c, are provided with the same height extending upwardly from the top end of the sidewall 1224. In contrast, the protrusions 1228 may be provided at different heights as needed.

In the example described above, the hand 352 of the transfer robot 351 passes through the substrate transfer space to transfer the substrate W onto the spin chuck 1400. However, contrast to this, an exemplary embodiment in which the hand 352 of the transfer robot 351 is inserted into the substrate transfer space when the hand 352 of the transfer robot 351 moves downwardly from an upper side of the processing space of the outer cup 1220 into the processing space of the outer cup 1220, and that the hand 352 enters the substrate transfer space to transfer the substrate W may be further included.

In the examples described above, it has been described that the nozzle arm 1640 passes through the nozzle entry space when the treatment solution nozzle 1620 moves in a straight line from the outer side of the outer cup 1220 to the inner side of the outer cup 1220. However, an exemplary embodiment in which the nozzle arm 1640 may be inserted into the nozzle entry space when the treatment solution nozzle 1620 moves downwardly from the top of the processing space of the outer cup 1220 into the processing space of the outer cup 1220, and that the nozzle arm 1640 enters through the nozzle entry space may be further included.

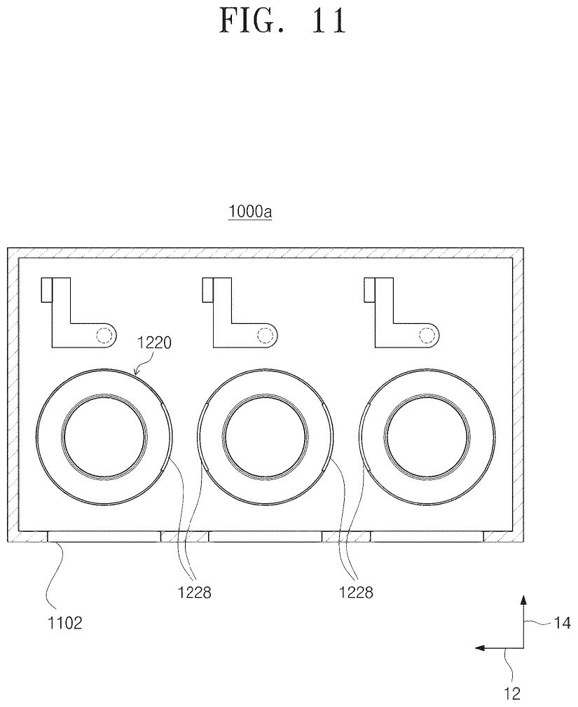

FIGS. 11 to 14 are diagrams illustrating a liquid treating chamber according to another exemplary embodiment of the present invention.

In the following, only configurations that differ from the liquid treating chamber 1000 previously described in FIGS. 8 to 10 will be described, and configurations that are the same as the liquid treating chamber 1000 described in FIGS. 8 to 10 are designated with the same symbols or omitted from description.

In the example described above, it has been described that the two protrusions 1228 are provided on each outer cup 1220. In contrast, however, as illustrated in FIG. 11, one outer cup 1220 may be provided only in a region adjacent to another outer cup 1220. Accordingly, when multiple outer cups 1220 are present within the liquid treating chamber 1000, only one protrusion 1228 may be provided on the outer cup 1220 located at the outermost side.

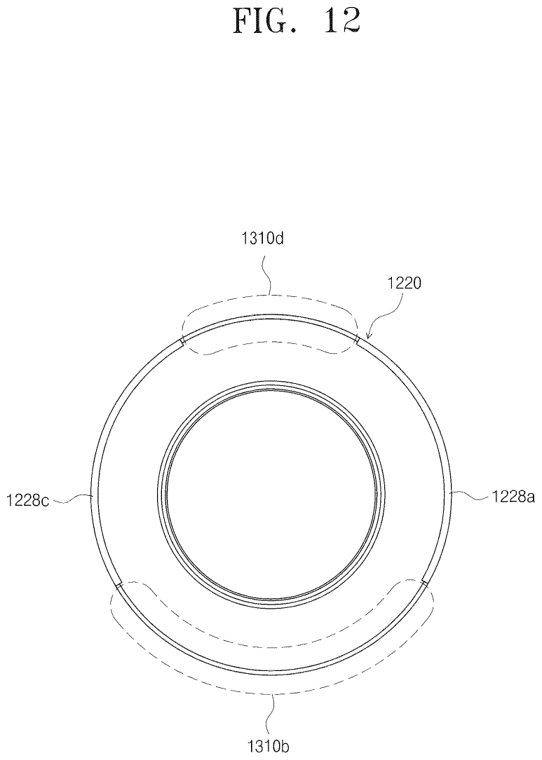

In the example described above, it has been described that the second region 1310b and the fourth region 1310d have the same width in the circumferential direction of the sidewall 1224. However, alternatively, the width of the second region 1310b may be provided to be wider than the width of the fourth region 1310d, as illustrated in FIG. 12.

In this case, the second region 1320b needs to have a width that is wider than the diameter of the substrate W, because the hand 352 of the transfer robot 351 and the substrate W need to be able to enter and exit the substrate transfer space provided in the second region 1310b. The fourth region 1320d also needs to be wide enough to allow the treatment solution nozzle 1620 to enter and exit the nozzle entry space because the treatment solution nozzle 1620 needs to be able to enter and exit the nozzle entry space provided in the fourth region 1310d.

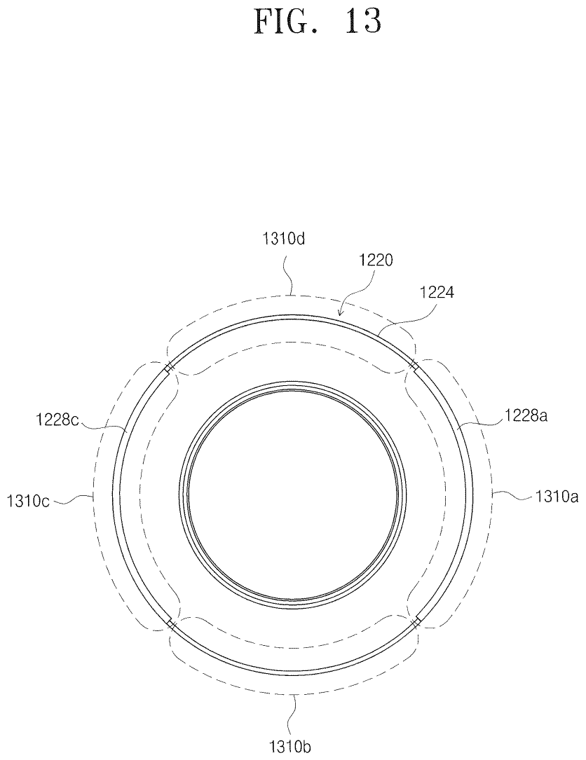

In the example described above, the widths of the second region 1310b and the fourth region 1310d are provided to be wider than the widths of the first region 1310a and the third region 1310c. In contrast, however, each of the regions may be of the same width, as illustrated in FIG. 13. That is, the central angle that each region makes with the circumferential center of the sidewall 1224 may be 90°.

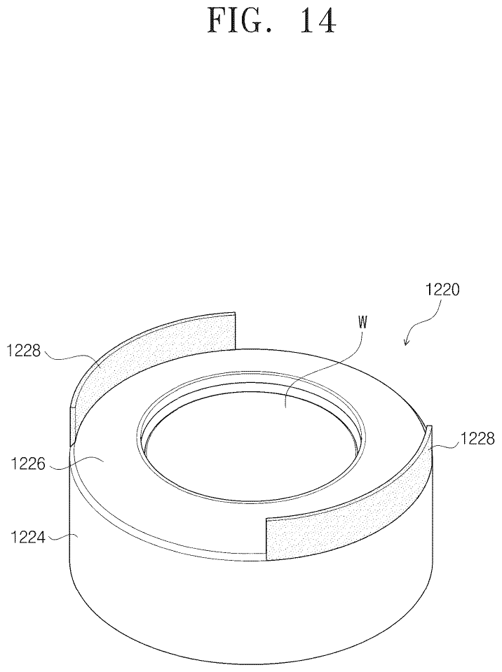

In the example above, it has been described that the protrusions are integrally formed with the sidewall. In contrast, however, as illustrated in FIG. 14, the protrusion 1228 may be provided separately from the sidewall and removably attached to the sidewall. In this case, the protrusions 1228 may be removed to perform cleaning or may be replaced when the liquid treatment of the substrate W is terminated or during maintenance of the liquid treating chamber 1000.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the disclosure, and all such modifications that would be obvious to one of ordinary skill in the art are intended to be included within the scope of the accompanying claims.

What is claimed is:

1. An apparatus for treating a substrate, the apparatus comprising:
a housing having an inner space;
a plurality of outer cups arranged in a row in the inner space, each having a processing space;
a spin chuck for supporting and rotating a substrate in each of the processing spaces; and
a treatment solution nozzle provided in a plurality to correspond to the plurality of outer cups, respectively, and for supplying a treatment solution onto the substrate supported by the spin chuck,
wherein the outer cup includes a sidewall surrounding the spin chuck,
the sidewall includes a first region and a second region located adjacent to each other along a circumferential direction thereof, and
the outer cup includes a first protrusion installed in the first region while extending upwardly on a top end of the sidewall.

2. The apparatus of claim 1, wherein the first region is a region facing another adjacent outer cup.

3. The apparatus of claim 2, wherein the sidewall further includes a third region and a fourth region, and
the third region faces the first region, and the fourth region faces the second region, and
the third region is provided with a second protrusion extending upwardly from the top end of the sidewall.

4. The apparatus of claim 3, wherein the first protrusion and the second protrusion are provided in a shape of an arc.

5. The apparatus of claim 3, further comprising:
a nozzle arm for supporting the treatment solution nozzle,
wherein the nozzle arm is provided to enter a space surrounded by the first protrusion, the second region, and the second protrusion and be movable to a top of the spin chuck.

6. The apparatus of claim 3, further comprising:
a transfer robot for transferring the substrate to the spin chuck,
wherein the transfer robot is provided to enter a space surrounded by the first protrusion, the fourth region, and the second protrusion to transfer the substrate to the spin chuck.

7. The apparatus of claim 3, wherein the first protrusion and the second protrusion each have the same height extending upwardly from the top end of the sidewall.

8. The apparatus of claim 3, wherein the first protrusion and the second protrusion are provided to be detachably.

9. The apparatus of claim 3, wherein a width of the second region in a circumferential direction is provided to be wider than a width of the first region in a circumferential direction and the third region in a circumferential direction.

10. The apparatus of claim 3, wherein the outer cup further includes a top wall, the top wall is provided to slope upwardly from the top end of the sidewall toward a central axis of the outer cup, and
a top end of each of the first protrusion and the second protrusion is provided to be positioned higher than a top end of the top wall.

11. An apparatus for treating a substrate, the apparatus comprising:
a housing having an inner space;
an outer cup provided in the inner space and having a processing space;
a spin chuck for supporting and rotating a substrate within the processing space;
a treatment solution nozzle for supplying a treatment solution onto the substrate supported by the spin chuck; and
a nozzle arm for supporting the treatment solution nozzle,
wherein the outer cup includes a sidewall surrounding the spin chuck,
the outer cup is provided with a protrusion extending upwardly from a top end of the sidewall, and
the protrusion is provided only in a portion of the sidewall.

12. The apparatus of claim 11, wherein the sidewall includes a first region and a second region located adjacent to each other along a peripheral direction thereof, and
the first region is provided with the protrusion.

13. The apparatus of claim 12, wherein the sidewall further includes a third region and a fourth region, and
the third region faces the first region, and the fourth region faces the second region, and
the protrusion is further provided in the third region.

14. The apparatus of claim 13, wherein the protrusion is provided in a shape of an arc.

15. The apparatus of claim 13, wherein one of spaces between the protrusions is provided as a space into which the nozzle arm enters.

16. The apparatus of claim 13, further comprising:
a transfer robot for transferring the substrate to the spin chuck,
wherein one of the spaces between the protrusions is provided as a space into which the transfer robot enters.

17. The apparatus of claim 11, wherein the outer cup further includes a top wall,
the top wall is provided to slope upwardly from the top end of the sidewall toward a central axis of the outer cup, and
a top end of the protrusion is provided to be positioned higher than a top end of the top wall.

18. An apparatus for treating a substrate, the apparatus comprising:
a housing having an inner space; and
a first outer cup and a second outer cup provided in the inner space, each having a processing space,
wherein the first outer cup and the second outer cup are arranged in a row in one direction in the inner space,
each of the first outer cup and the second outer cup includes:
a spin chuck for supporting and rotating a substrate within the processing space;
a treatment solution nozzle for supplying a treatment solution onto the substrate supported by the spin chuck;
a nozzle arm for supporting the treatment solution nozzle; and
a sidewall surrounding the spin chuck, and
the first outer cup includes a first region, a second region, a third region, and a fourth region in the sidewall,
the first region is provided with a first protrusion extending upwardly from the top end of the sidewall,
the first protrusion is provided in a shape of an arc, and
the first region is a region facing the second outer cup.

19. The apparatus of claim 18, wherein the third region faces the first region, and the fourth region faces the second region, and
the third region is provided with a second protrusion extending upwardly from the top end of the sidewall, and
the second protrusion is provided in a shape of an arc.

20. The apparatus of claim 19, further comprising:
a transfer robot for transferring the substrate to the spin chuck,
wherein one of spaces between the first protrusion and the second protrusion is provided as a space into which the nozzle arm enters, and
another one of the spaces between the first protrusion and the second protrusion is provided as a space into which the transfer robot enters.
